(19) United States
(12) Patent Application Publication
(10) Pub. No.: US 2025/0331232 A1
(43) Pub. Date: Oct. 23, 2025

(54) SEMICONDUCTOR DEVICE INCLUDING HIGH PERFORMANCE TRANSISTORS, AND METHOD FOR MANUFACTURING THE SAME

(71) Applicant: TAIWAN SEMICONDUCTOR MANUFACTURING COMPANY, LTD., Hsinchu (TW)

(72) Inventors: Hsin-Huang LIN, Hsinchu (TW); Ta-Chun LIN, Hsinchu (TW); Chun-Sheng LIANG, Hsinchu (TW); Yi-Ren CHEN, Hsinchu (TW); Chih-Hao CHANG, Hsinchu (TW); Jhon Jhy LIAW, Hsinchu (TW)

(73) Assignee: TAIWAN SEMICONDUCTOR MANUFACTURING COMPANY, LTD., Hsinchu (TW)

(21) Appl. No.: 18/637,751

(22) Filed: Apr. 17, 2024

(51) Int. Cl. H01L 29/423; H01L 21/8238; H01L 27/092; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/017; H10D 84/0167; H10D 84/017; H10D 84/0186; H10D 84/038; H10D 84/85

(57) ABSTRACT

A semiconductor device includes an n-type transistor, a first contact segment, a p-type transistor and a second contact segment. Each of the n-type transistor and the p-type transistor includes a first source/drain region and a second source/drain region. The first contact segment partially overlaps the first source/drain region of the n-type transistor, and is in contact with the first source/drain region of the n-type transistor. The second contact segment partially overlaps the first source/drain region of the p-type transistor, and is in contact with the first source/drain region of the p-type transistor. A width of a portion of the first contact segment that overlaps the first source/drain region of the n-type transistor is different from a width of a portion of the second contact segment that overlaps the first source/drain region of the p-type transistor.

### BACKGROUND

The semiconductor integrated circuit (IC) industry has, over the decades, experienced tremendous advancements and is still undergoing vigorous development. With dramatic advances in technology, the industry pays much attention on the development of transistors with high performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic top view of a semiconductor device in accordance with some embodiments.

FIGS. 2 to 5 are schematic sectional views of the semiconductor device respectively taken along lines A1-A1′, B1-B1′, A2-A2′ and B2-B2′ of FIG. 1 in accordance with some embodiments.

FIG. 6 is a schematic top view of a semiconductor device in accordance with some embodiments.

FIGS. 7 to 10 are schematic sectional views of the semiconductor device respectively taken along lines A1-A1′, B1-B1′, A2-A2′ and B2-B2′ of FIG. 6 in accordance with some embodiments.

FIG. 11 is a schematic top view of a semiconductor device in accordance with some embodiments.

FIG. 12 is a schematic top view of a semiconductor device in accordance with some embodiments.

FIGS. 13 and 14 are flow charts illustrating a method for manufacturing a semiconductor device in accordance with some embodiments.

FIGS. 15 to 34 illustrate intermediate stages of the method for manufacturing a semiconductor device in accordance with some embodiments, where FIGS. 15 and 26 are schematic top views and FIGS. 16-25 and 27-34 are schematic sectional views.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly.

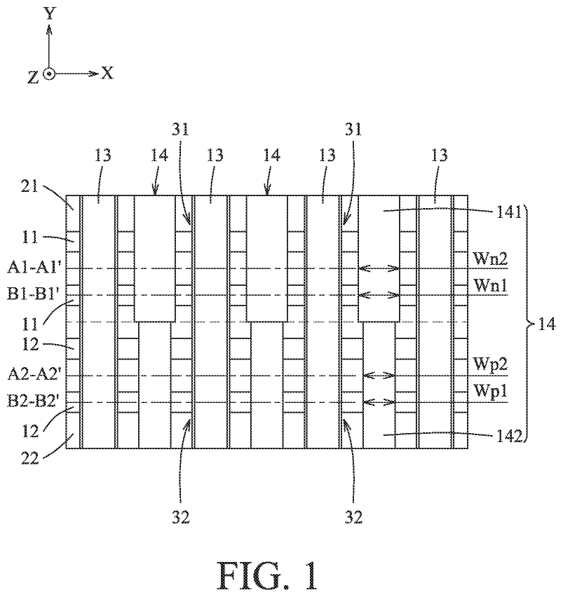

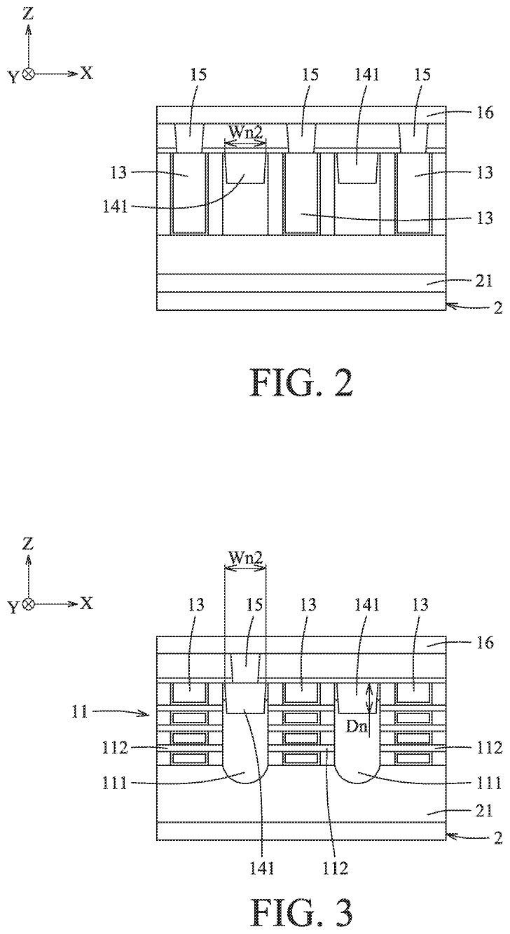

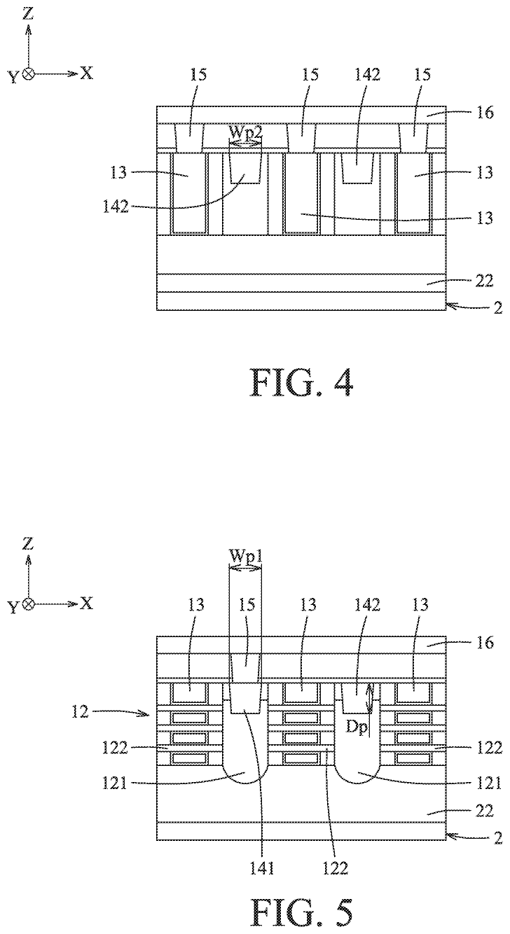

FIG. 1 is a schematic top view of a semiconductor device in accordance with some embodiments. FIGS. 2 to 5 are schematic sectional views of the semiconductor device respectively taken along lines A1-A1′, B1-B1′, A2-A2′ and B2-B2′ of FIG. 1 in accordance with some embodiments. Referring to FIGS. 1 to 5, the semiconductor device includes a plurality of oxide diffusion areas 11, 12, a plurality of gate electrodes 13, a plurality of contact lines 14, a plurality of vias 15 and a plurality of conductive lines 16. Only the oxide diffusion areas 11, 12, the gate electrodes 13 and the contact lines 14 are depicted in FIG. 1. Each of the oxide diffusion areas 11, 12 extends in a first direction (e.g., an X direction) transverse to a second direction (e.g., a Z direction), which extends from bottom to top of the semiconductor device. The oxide diffusion areas 11 reside in a p-type well 21 of a substrate 2. The oxide diffusion areas 12 reside in an n-type well 22 of the substrate 2. Each of the gate electrodes 13 extends in a third direction (e.g., a Y direction) transverse to the first direction and the second direction, and partially overlaps each of the oxide diffusion areas 11, 12. A plurality of source/drain regions 111 and a plurality of channel features 112 are formed in each of the oxide diffusion areas 11. A plurality of source/drain regions 121 and a plurality of channel features 122 are formed in each of the oxide diffusion areas 12. In each of the oxide diffusion areas 11, 12, two adjacent ones of the source/drain regions 111/121 are spaced apart from each other by a corresponding one of the channel features 112/122 in the X direction, and each of the channel features 112/122 is connected to at least one of the source/drain regions 111/121 that is adjacent to the channel feature 112/122. The gate electrodes 13 are disposed to respectively control current flows in the channel features 112/122 in each of the oxide diffusion areas 11, 12. Each of the contact lines 14 extends in the Y direction, and is disposed to partially overlap and be in contact with a corresponding one of the source/drain regions 111/121 in each of the oxide diffusion areas 11, 12. Each of the vias 15 is disposed on and in contact with a corresponding one of the gate electrodes 13 and the contact lines 14. Each of the conductive lines 16 is disposed over the vias 14, and is in contact with at least one of the vias 15. With respect to each of the oxide diffusion areas 11, one of the gate electrodes 13, one of the channel features 112 controlled by said one of the gate electrodes 13, and two of the source/drain regions 111 adjacent to said one of the channel features 112 may cooperatively constitute an n-type transistor 31. With respect to each of the oxide diffusion areas 12, one of the gate electrodes 13, one of the channel features 122 controlled by said one of the gate electrodes 13, and two of the source/drain regions 121 adjacent to said one of the channel features 122 may cooperatively constitute a p-type transistor 32.

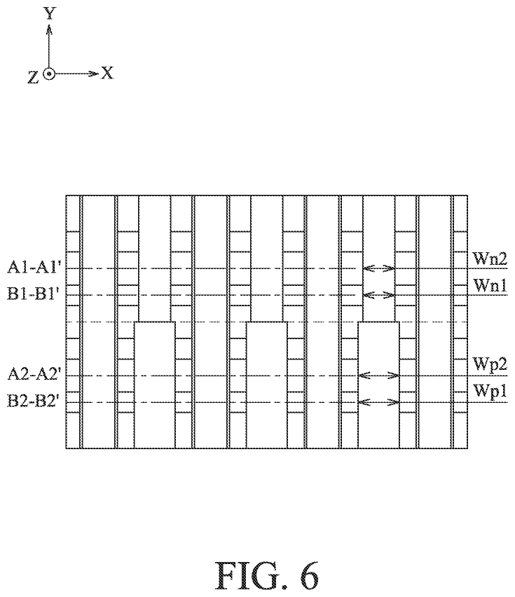

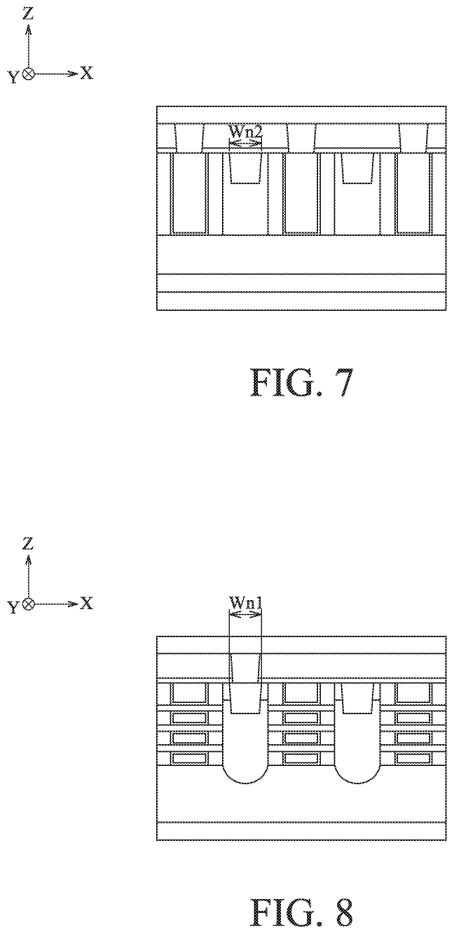

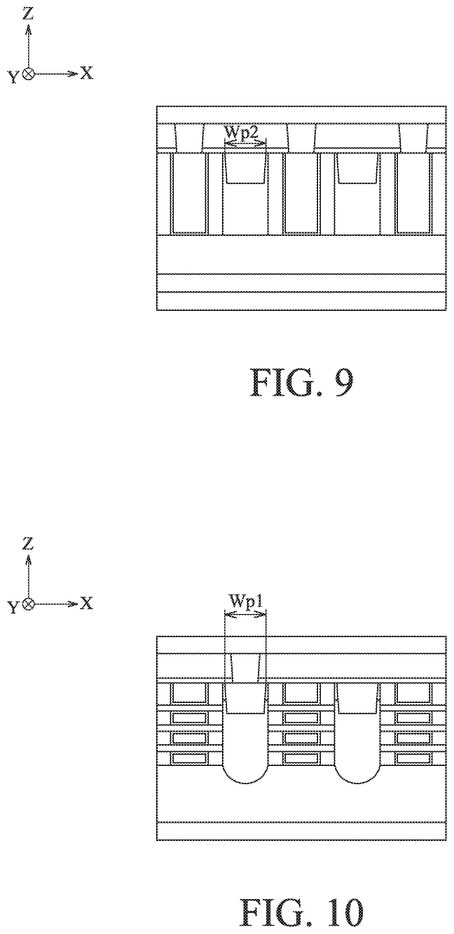

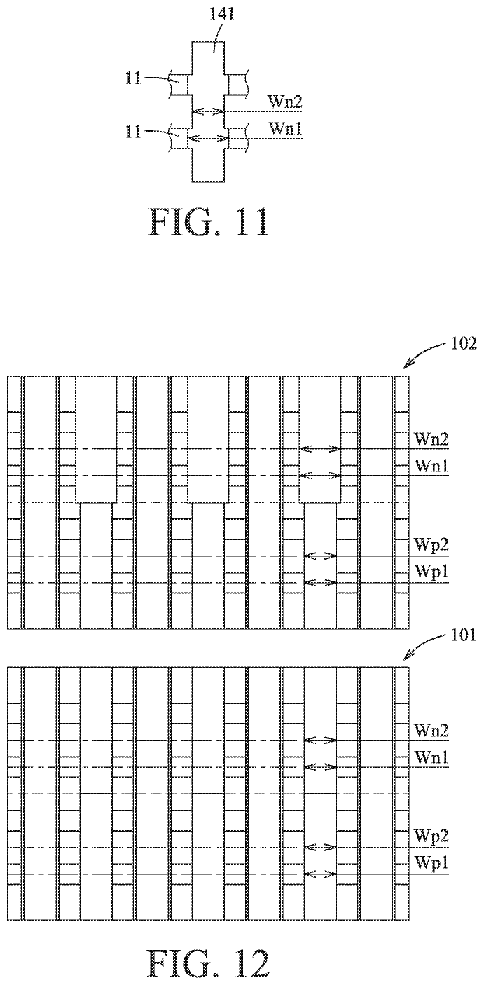

Each of the contact lines 14 includes a first contact segment 141 that is disposed on the p-type well 21, and a second contact segment 142 that is disposed on the n-type well 22. Portions of the first contact segments 141 of the contact lines 14 that overlap the source/drain regions 111 in the oxide diffusion areas 11 may have the same width of Wn1 in the X direction. Portions of the first contact segments 141 of the contact lines 14 that are non-overlapping with the source/drain regions 111 in the oxide diffusion areas 11 may have the same width of Wn2 in the X direction. Portions of the second contact segments 142 of the contact lines 14 that overlap the source/drain regions 121 in the oxide diffusion areas 12 may have the same width of Wp1 in the X direction. Portions of the second contact segments 142 of the contact lines 14 that are non-overlapping with the source/drain regions 121 in the oxide diffusion areas 12 may have the same width of Wp2 in the X direction. Wn1 may be larger than or smaller than (i.e., different from) Wp1, and may be larger than, equal to or smaller than Wn2. Wp1 may be larger than, equal to or smaller than Wp2. FIGS. 1 to 5 depict an example where Wn1=Wn2>Wp1=Wp2. FIGS. 6 to 10 depict an example where Wn1=Wn2<Wp1=Wp2. FIG. 11 depicts an example where Wn1>Wn2. Wn1 and Wp1 may be adjusted independently so as to optimize both of performance of the n-type transistors 31 (which are cooperatively constituted by the channel features 112 and the source/drain regions 111 in the oxide diffusion areas 11, and the gate electrodes 13) and performance of the p-type transistors 32 (which are cooperatively constituted by the channel features 122 and the source/drain regions 121 in the oxide diffusion areas 12, and the gate electrodes 13).

In some embodiments, a difference between Wn1 and Wp1 (i.e., |Wn1−Wp1|) may fall within a range of from about 0.5 nm to about 10 nm. In some embodiments where Wn1 is different from Wn2, a difference between Wn1 and Wn2 (i.e., |Wn1−Wn2|) may fall within a range of from about 0.5 nm to about 10 nm. In some embodiments, Wn1 may be larger than Wn2 for capacitance reduction. In some embodiments where Wp1 is different from Wp2, a difference between Wp1 and Wp2 (i.e., |Wp1−Wp2|) may fall within a range of from about 0.5 nm to about 10 nm. In some embodiments, Wp1 may be larger than Wp2 for capacitance reduction.

It should be noted that decreasing Wp1 can prevent short circuit of the p-type transistors 32, thereby increasing yield of the semiconductor device. In addition, for each contact line 14 that is in contact with a via 15, the width of each portion of the first contact segment 141 of the contact line 14 that is in contact with the via 15 may be larger than the width of each portion of the first contact segment 141 of the contact line 14 that is not in contact with the via 15, and the width of each portion of the second contact segment 142 of the contact line 14 that is in contact with the via 15 may be larger than the width of each portion of the second contact segment 142 of the contact line 14 that is not in contact with the via 15. Moreover, all of the contact lines 14 may be formed from a front side of the substrate 2 as shown in FIGS. 2 to 5, or may be formed from a back side of the substrate 2. Alternatively, some of the contact lines 14 may be formed from the front side of the substrate 2, and the other ones of the contact lines 14 may be formed from the back side of the substrate 2. Furthermore, with respect to each of the contact lines 14, a shortest distance (in the X direction) between adjacent sides of the first contact segment 141 and one of the gate electrodes 13 that is adjacent to the contact line 14 may be greater than, equal to or smaller than a shortest distance (in the X direction) between adjacent sides of the second contact segment 142 and said one of the gate electrodes 13.

The first contact segments 141 of the contact lines 14 may have the same height of Dn in the Z direction. The second contact segments 142 of the contact lines 14 may have the same height of Dp in the Z direction. Dn may be larger than, equal to or smaller than Dp. FIGS. 2 to 5 depict an example where Dn=Dp. In some embodiments, Dp may be smaller than Dn, so as to prevent short circuit of the p-type transistors 32.

It should be noted that each of the n-type transistors 31 and the p-type transistors 32 may be a nanosheet gate-all-around field effect transistor (GAAFET) as shown in FIGS. 2 to 5, or may be a planar FET, a fin FET (FinFET), a nanowire GAAFET, a fork-sheet FET, a complementary FET (CFET) or other suitable FET.

FIG. 12 is a schematic top view of a semiconductor device in accordance with some embodiments. The semiconductor device includes a first circuit 101 and a second circuit 102. The second circuit 102 has a connected poly pitch that is larger than a connected poly pitch of the first circuit 101, and may be identical to any one of the semiconductor devices depicted in FIGS. 1 and 6 (i.e., Wn1≠Wp1). FIG. 12 depicts an example where the second circuit 102 is identical to the semiconductor device depicted in FIG. 1 (i.e., Wn1>Wp1). The first circuit 101 is similar to any one of the semiconductor devices depicted in FIGS. 1 and 6, but differs from any one of the semiconductor devices depicted in FIGS. 1 and 6 in that Wn1=Wp1. In some embodiments, Wn1 of the second circuit 102 is larger than Wn1 of the first circuit 101, and a ratio of Wn1 of the second circuit 102 to Wn1 of the first circuit 101 may be no less than about 1.1. In some embodiments, Wp1 of the second circuit 102 is larger than Wp1 of the first circuit 101, and a ratio of Wp1 of the second circuit 102 to Wp1 of the first circuit 101 may be no less than about 1.1.

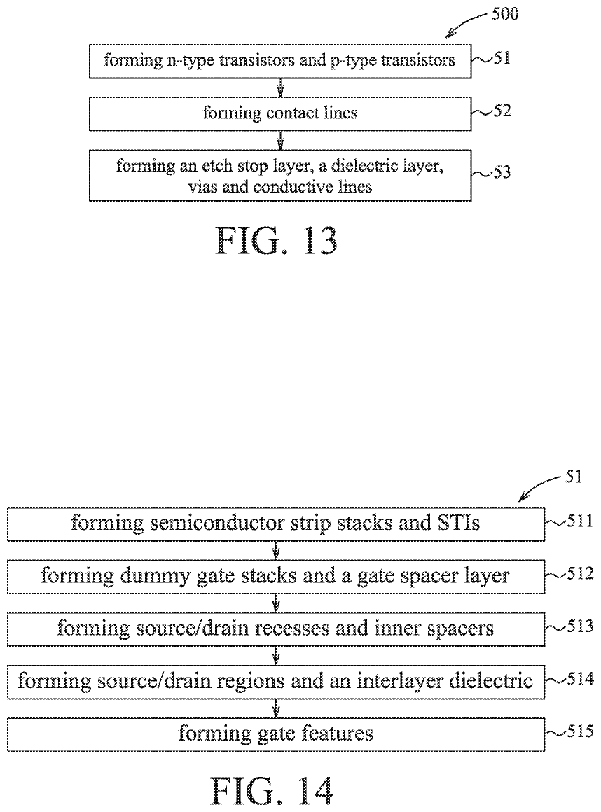

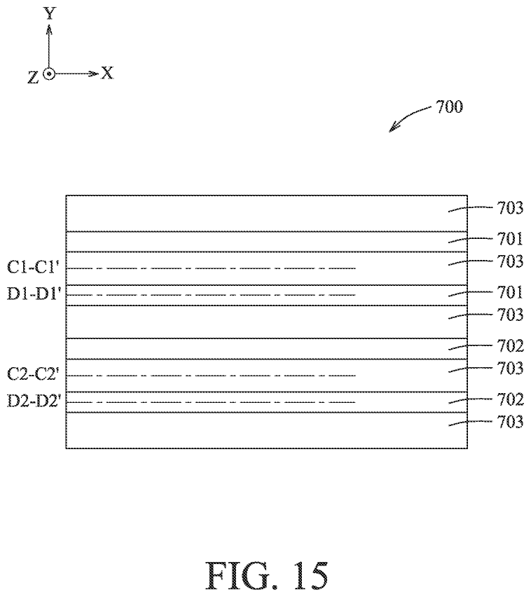

FIGS. 13 and 14 are flow charts illustrating a method 500 for manufacturing a semiconductor device in accordance with some embodiments. FIGS. 15 to 34 are schematic top or sectional views of semiconductor structures 700 during various stages of the method 500. The method 500 and the semiconductor structures 700 will be described together below. It should be noted that additional steps can be provided before, after or during the method 500, and some of the steps described herein may be replaced by other steps or be eliminated. Similarly, further additional features may be present in the semiconductor structures 700, and/or features present may be replaced or eliminated in additional embodiments.

Referring to FIGS. 13 and 25, the method 500 begins at step 51, where a plurality of n-type transistors 81 and a plurality of p-type transistors 82 are formed on a substrate 900. In some embodiments where each of the n-type transistors 81 and the p-type transistors 82 is a nonosheet GAAFET, step 51 may include sub-steps 511-515 as shown in FIG. 14.

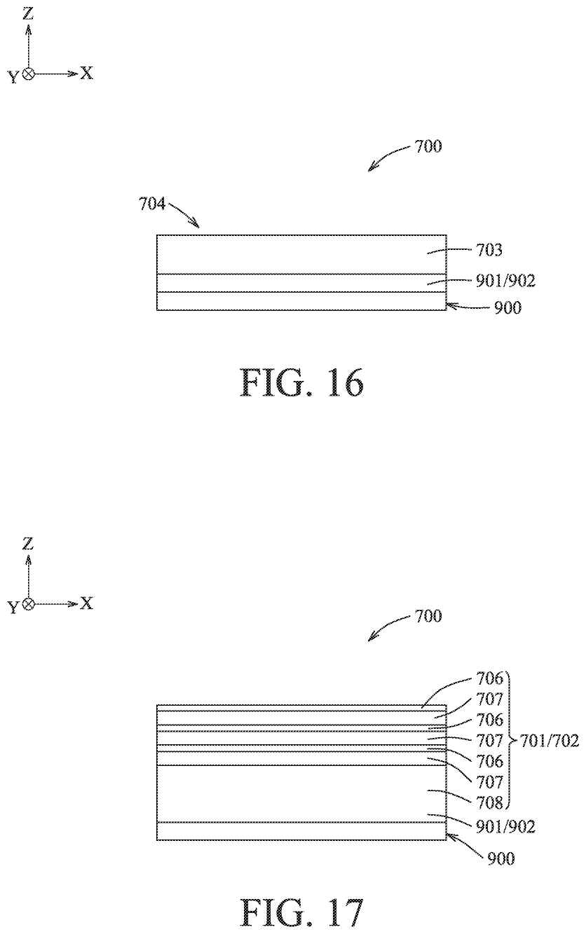

Referring to FIGS. 14-17, where FIG. 16 illustrates a schematic sectional view taken along any one of line C1-C1′ and line C2-C2′ of FIG. 15 and FIG. 17 illustrates a schematic sectional view taken along any one of line D1-D1′ and line D2-D2′ of FIG. 15, in sub-step 511, a plurality of semiconductor strip stacks 701, 702 and a plurality of shallow trench isolations (STIs) 703 are formed on a substrate 900. The substrate 900 includes a p-type well 901 an n-type well 902. Each of the semiconductor strip stacks 701 is disposed on the p-type well 901, and extends in a first direction (e.g., an X direction) transverse to a second direction (e.g., a Z direction), which extends from bottom to top of the semiconductor structure 700. Each of the semiconductor strip stacks 702 is disposed on the n-type well 902, and extends in the X direction. Each of the semiconductor strip stacks 701, 702 serves as an oxide diffusion area, and includes a plurality of first semiconductor strips 706, a plurality of second semiconductor strips 707 and a substrate strip 708. The semiconductor strip stacks 701, 702 are spaced apart from each other in a third direction (e.g., a Y direction) transverse to the first direction and the second direction. The STIs 703 are disposed on the p-type well 901 and the n-type well 902, and fill lower portions of a plurality of recesses 704 that define the semiconductor strip stacks 701, 702. In some embodiments, the semiconductor strip stacks 701, 702 may be formed by: (a) depositing multiple first semiconductor sheets for forming the first semiconductor strips 706 of the semiconductor strip stacks 701, 702 and multiple second semiconductor sheets for forming the second semiconductor strips 707 of the semiconductor strip stacks 701, 702 on the p-type well 901 and the n-type well 902 in an alternating manner using, for example, chemical vapor deposition (CVD), plasma enhanced chemical vapor deposition (PECVD), physical vapor deposition (PVD), atomic layer deposition (ALD), other suitable techniques, or combinations thereof; and (b) patterning the first semiconductor sheets, the second semiconductor sheets, the p-type well 901 and the n-type well 902 to form the first semiconductor strips 706, the second semiconductor strips 707 and the substrate strips 708 of the semiconductor strip stacks 701, 702. In some embodiments, the first semiconductor sheets, the second semiconductor sheets, the p-type well 901 and the n-type well 902 may be patterned using a photolithography process and an etching process. The photolithography process may include, for example, but not limited to, coating a topmost one of the first semiconductor sheets and the second semiconductor sheets with a photoresist, soft-baking, exposing the photoresist through a photomask, post-exposure baking, developing the photoresist, and hard-baking, so as to form a patterned photoresist. The etching process may be implemented by etching the first semiconductor sheets, the second semiconductor sheets, the p-type well 901 and the n-type well 902 through the patterned photoresist using, for example, dry etching, wet etching, reactive ion etching (RIE), atomic layer etching (ALE), other suitable techniques, or combinations thereof. The patterned photoresist may be removed after the etching process. In some embodiments, the STIs 703 may be formed by: (a) depositing a dielectric layer for forming the STIs 703 over the p-type well 901, the n-type well 902 and the semiconductor strip stacks 701, 702 using, for example, CVD, PECVD, PVD, ALD, other suitable techniques, or combinations thereof; (b) removing an excess of the dielectric layer using, for example, chemical mechanical polishing (CMP), or other suitable planarization techniques, so as to expose top surfaces of the semiconductor strip stacks 701, 702; and (c) etching back the dielectric layer using, for example, dry etching, wet etching, RIE, ALE, other suitable techniques, or combinations thereof, so as to form the STIs 703. In some embodiments, the substrate 900 may be a silicon substrate. In some embodiments, the first semiconductor sheets for forming the first semiconductor strips 706 may be silicon sheets, and the second semiconductor sheets for forming the second semiconductor strips 707 may be silicon germanium sheets, but the disclosure is not limited in this respect. In some embodiments, the dielectric layer for forming the STIs 703 may include, for example, silicon oxide, silicon nitride, silicon oxynitride, high dielectric constant materials, other suitable materials, or combinations thereof.

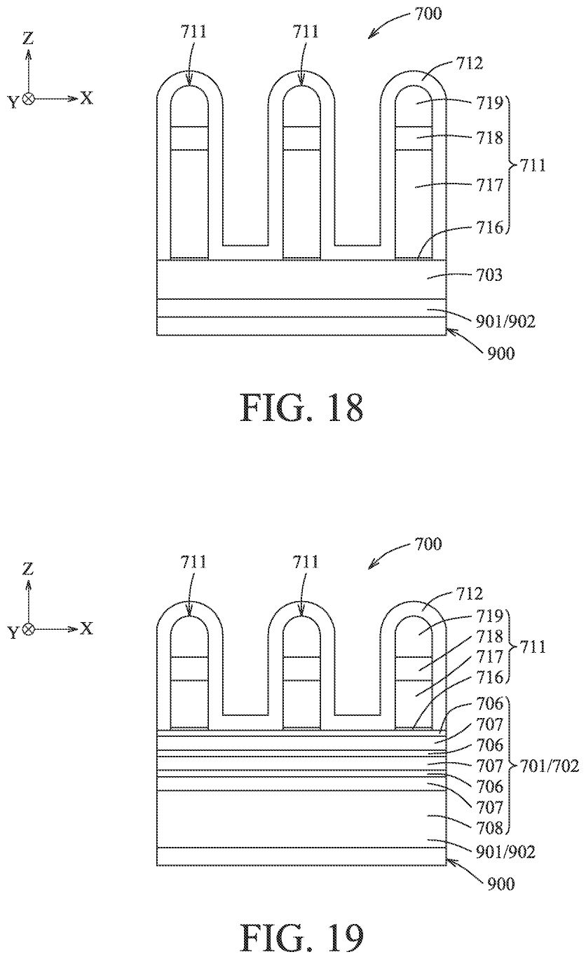

Referring to FIGS. 14, 18 and 19, where FIG. 18 is a view similar to FIG. 16 and FIG. 19 is a view similar to FIG. 17, in sub-step 512, a plurality of dummy gate stacks 711 are formed over the semiconductor strip stacks 701, 702 and the STIs 703, and then a gate spacer layer 712 is formed over the dummy gate stacks 711, the semiconductor strip stacks 701, 702 and the STIs 703. Each of the dummy gate stacks 711 extends in the Y direction, and includes a dummy gate dielectric 716, a dummy gate electrode 717, a polish-stop layer 718 and a hard mask layer 719 that are arranged from bottom to top in the given order. The gate spacer layer 712 may have a single layer structure or a multi-layered structure. In some embodiments, the dummy gate stacks 711 may be formed by: (a) depositing a first layer for forming the dummy gate dielectrics 716 of the dummy gate stacks 711, a second layer for forming the dummy gate electrodes 717 of the dummy gate stacks 711, a third layer for forming the polish-stop layers 718 of the dummy gate stacks 711, and a fourth layer for forming the hard mask layers 719 of the dummy gate stacks 711 using, for example, CVD, PECVD, PVD, ALD, other suitable techniques, or combinations thereof; and (b) patterning the first to fourth layers to form the dummy gate dielectrics 716, the dummy gate electrodes 717, the polish-stop layers 718 and the hard mask layers 719 using a photolithography process and an etching process similar to those used to pattern the first semiconductor sheets, the second semiconductor sheets, the p-type well 901 and the n-type well 902 in sub-step 511 of the method 500. In some embodiments, the gate spacer layer 712 may be conformally formed using, for example, CVD, ALD, other suitable techniques, or combinations thereof. In some embodiments, the first layer for forming the dummy gate dielectrics 716 may include, for example, silicon oxide, other suitable dielectric materials, or combinations thereof. In some embodiments, the second layer for forming the dummy gate electrodes 717 may include, for example, polycrystalline silicon, microcrystal silicon, amorphous silicon, other suitable materials, or combinations thereof. In some embodiments, the third layer for forming the polish-stop layers 718 may include, for example, silicon nitride, silicon oxide, other nitrides, other oxides, other suitable materials, or combinations thereof. In some embodiments, the fourth layer for forming the hard mask layers 719 may include, for example, silicon nitride, silicon oxide, silicon oxynitride, other suitable materials, or combinations thereof. In some embodiments, the gate spacer layer 712 may include, for example, silicon nitride, silicon oxycarbide, silicon oxycarbonitride, silicon carbonitride, other suitable materials, or combinations thereof.

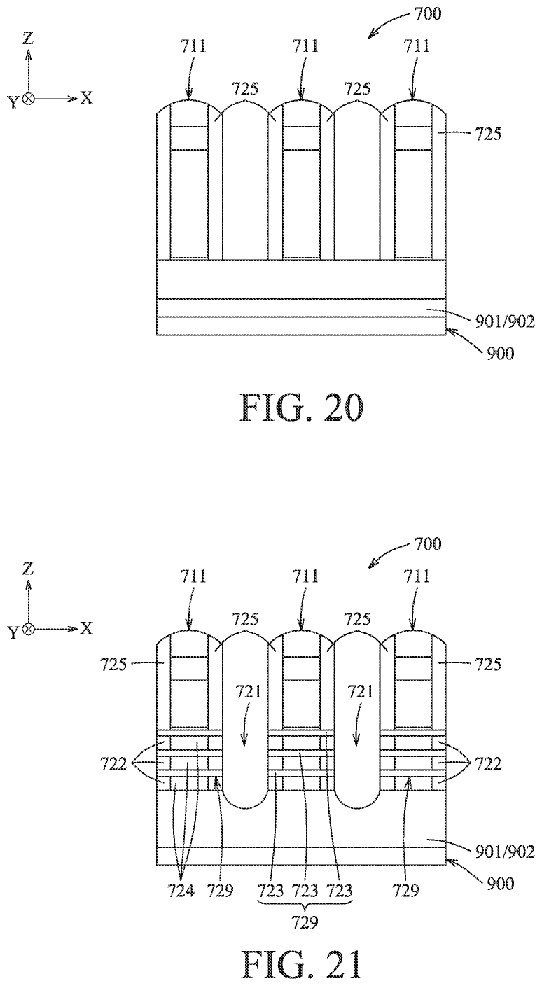

Referring to FIGS. 14 and 18-21, where FIG. 20 is a view similar to FIG. 16 and FIG. 21 is a view similar to FIG. 17, in sub-step 513, a plurality of source/drain recesses 721 and a plurality of inner spacers 722 are formed. The source/drain recesses 721 are formed in the semiconductor strip stacks 701, 702 at positions exposed from the dummy gate stacks 711, and are spaced apart from each other in the X direction, so that the first semiconductor strips 706 of the semiconductor strips stacks 701, 702 are formed into channel layers 723 and the second semiconductor strips 707 of the semiconductor strips stacks 701, 702 are formed into sacrificial layers 724. A combination of the channel layers 723 that are stacked together serves as a channel feature 729. In some embodiments, the source/drain recesses 721 may be formed by etching the semiconductor strip stacks 701, 702 using, for example, dry etching, wet etching, RIE, ALE, other suitable techniques, or combinations thereof. At the same time, horizontal portions of the gate spacer layer 712 are removed. Vertical portions of the gate spacer layer 712 that remain on the sidewalls of the dummy gate stacks 711 serve as gate spacers 725. Thereafter, the sacrificial layers 724 are etched to form recesses at side portions thereof, and the inner spacers 722 are formed to fill the recesses. In some embodiments, the sacrificial layers 724 may be etched using, for example, dry etching, wet etching, RIE, ALE, other suitable techniques, or combinations thereof. In some embodiments, the inner spacers 722 may include, for example, oxide-based material (e.g., silicon oxide), carbide-based material (e.g., silicon carbide), oxynitride-based material (e.g., silicon oxynitride), nitride-based material (e.g., silicon nitride), other suitable dielectric materials, or combinations thereof.

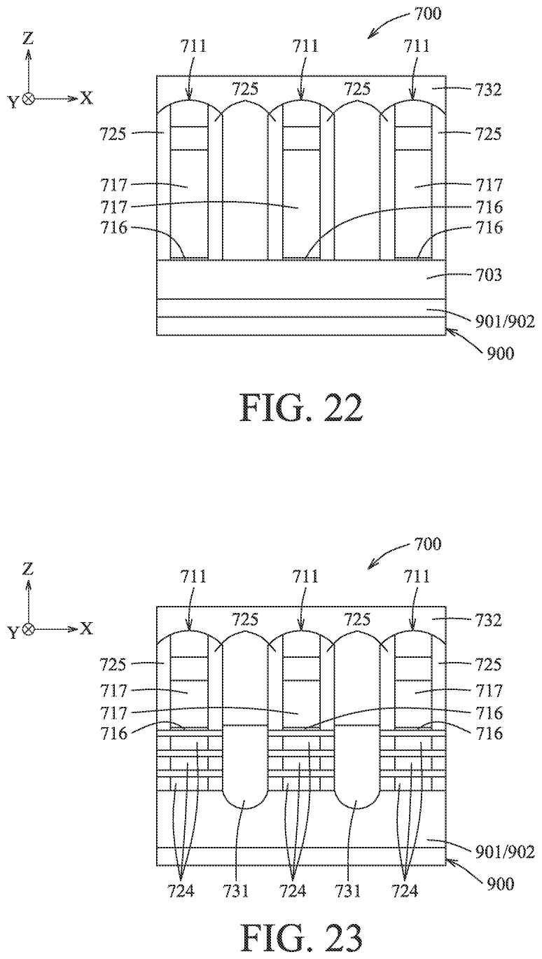

Referring to FIGS. 14 and 20-23, where FIG. 22 is a view similar to FIG. 16 and FIG. 23 is a view similar to FIG. 17, in sub-step 514, a plurality of source/drain regions 731 are respectively formed in the source/drain recesses 721, and then an interlayer dielectric 732 is formed over the dummy gate stacks 711, the gate spacers 725, the source/drain regions 731 and the STIs 703. In some embodiments, the source/drain regions 731 may be formed epitaxially using, for example, cyclic deposition-etch (CDE) process, other suitable techniques, or combinations thereof. In some embodiments, the source/drain regions 731 disposed on the p-type well 901 may include, for example, crystalline silicon (or other suitable materials) doped with an n-type impurity, and the source/drain regions 731 disposed on the n-type well 902 may include, for example, crystalline silicon (or other suitable materials) doped with a p-type impurity. In some embodiments, the interlayer dielectric 732 may be formed using, for example, CVD, PECVD, PVD, ALD, other suitable techniques, or combinations thereof. In some embodiments, the interlayer dielectric 732 may include, for example, silicon oxide, silicon nitride, silicon oxynitride, phosphosilicate glass (PSG), borophosphosilicate glass (BPSG), spin-on glass (SOG), fluorosilicate glass (FSG), carbon-doped silicon oxides (e.g., SiCOH), xerogel, aerogel, parylene, divinylsiloxane-bis-benzocyclobutene-based (BCB-based) dielectric materials, polyimide, other suitable materials, or combinations thereof.

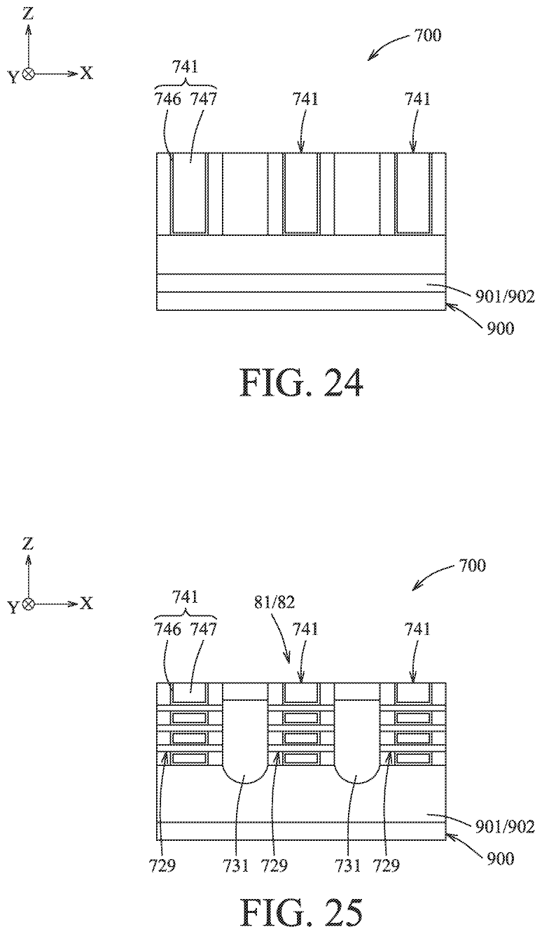

Referring to FIGS. 14 and 22-25, where FIG. 24 is a view similar to FIG. 16 and FIG. 25 is a view similar to FIG. 17, in sub-step 515, excesses of the interlayer dielectric 732, the dummy gate stacks 711 and the gate spacers 725 are removed to expose the dummy gate electrodes 717 of the dummy gate stacks 711, then the dummy gate electrodes 717 and the dummy gate dielectric 716 of the dummy gate stacks 711 and the sacrificial layers 724 are removed, and finally a plurality of gate features 741 are formed. Each of the gate features 741 extends in the Y direction, and surrounds a respective one of the channel features 729 that are formed in each of the semiconductor strip stacks 701, 702 (see FIG. 17). Each of the gate features 741 includes a gate dielectric 746 that is formed on the corresponding channel features 729, and a gate electrode 747 that is formed to surround the channel features 729 covered by the gate dielectric 746. Each of the n-type transistors 81 is constituted by a corresponding one of the channel features 729 that is disposed on the p-type well 901, two corresponding ones of the source/drain regions 731 that are disposed on the p-type well 901 and adjacent to said corresponding one of the channel features 729, and a corresponding one of the gate electrodes 747 of the gate features 741 that surrounds said corresponding one of the channel features 729. Each of the p-type transistors 82 is constituted by a corresponding one of the channel features 729 that is disposed on the n-type well 902, two corresponding ones of the source/drain regions 731 that are disposed on the n-type well 902 and adjacent to said corresponding one of the channel features 729, and a corresponding one of the gate electrodes 747 of the gate features 741 that surrounds said corresponding one of the channel features 729. In some embodiments, the semiconductor structure 700 depicted in FIGS. 22 and 23 may be subjected to a planarization treatment (e.g., CMP) to remove the excesses of the interlayer dielectric 732, the dummy gate stacks 711 and the gate spacers 725. In some embodiments, the dummy gate electrodes 717 and the dummy gate dielectrics 716 of the dummy gate stacks 711 and the sacrificial layers 724 may be removed using, for example, drying etching, wet etching, RIE, ALE, other suitable techniques, or combinations thereof. In some embodiments, the gate dielectrics 746 and the gate electrodes 747 of the gate features 741 may be formed using, for example, PVD, CVD, ALD, other suitable techniques, or combinations thereof. In some embodiments, each of the gate dielectrics 746 may include, for example, Hf-based dielectric materials, Zr-based dielectric materials, Al-based dielectric materials, Ti-based dielectric materials, Ba-based dielectric materials, RE element-based dielectric materials, nitrides, other suitable high dielectric constant materials, or combinations thereof. In some embodiments, each of the gate electrodes 747 may include, for example, a metal (e.g., copper, aluminum, titanium, tantalum, cobalt, tungsten, or the like, or alloys thereof), polysilicon, metal-containing nitrides (e.g., TaN), metal-containing silicides (e.g., NiSi), metal-containing carbides (e.g., TaC), other suitable conductive materials, or combinations thereof.

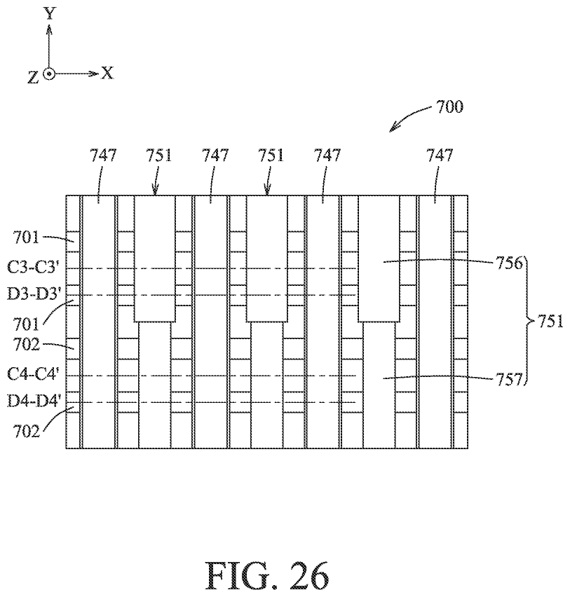

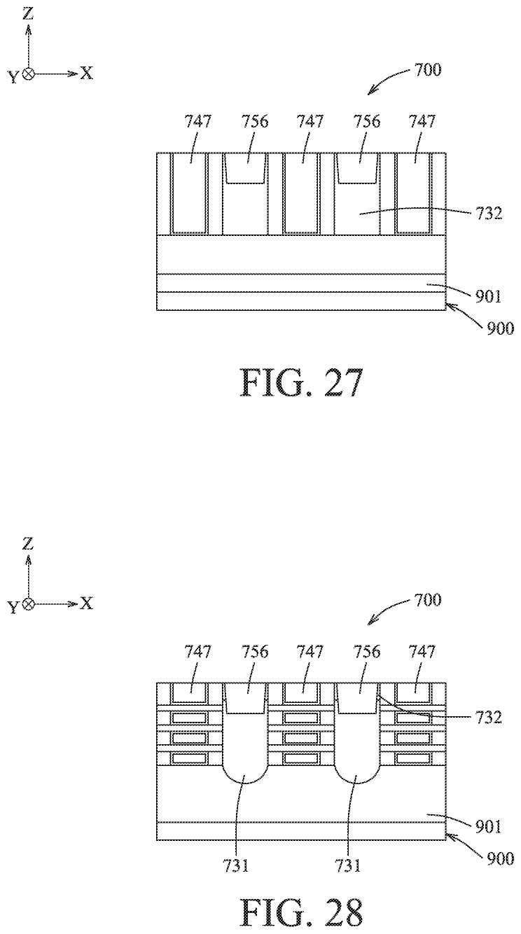

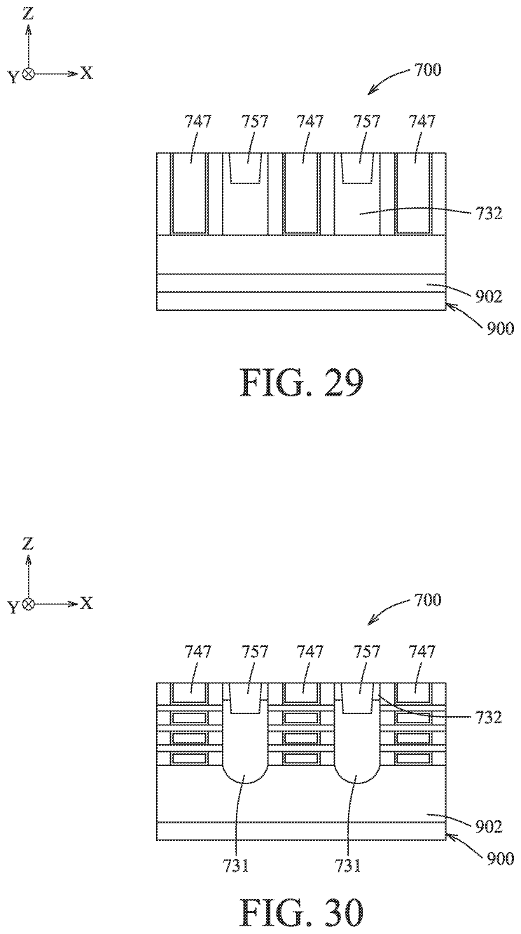

Referring to FIGS. 13 and 26-30, the method 500 then proceeds to step 52, where a plurality of contact lines 751 are formed. FIG. 27 illustrates a schematic sectional view taken along line C3-C3′ of FIG. 26. FIG. 28 illustrates a schematic sectional view taken along line D3-D3′ of FIG. 26. FIG. 29 illustrates a schematic sectional view taken along line C4-C4′ of FIG. 26. FIG. 30 illustrates a schematic sectional view taken along line D4-D4′ of FIG. 26. Each of the contact lines 751 extends in the Y direction, is disposed between two adjacent ones of the gate electrodes 747, and includes a first contact segment 756 and a second contact segment 757, where the first contact segment 756 and the second contact segment 757 have different widths in the X direction, the first contact segment 756 is in contact with the source/drain regions 731 that are disposed between said two adjacent ones of the gate electrodes 747 and on the p-type well 901, and the second contact segment 757 is in contact with the source/drain regions 731 that are disposed between said two adjacent ones of the gate electrodes 747 and on the n-type well 902. In some embodiments, the contact lines 751 may be formed by: (a) patterning the interlayer dielectric 732 and the source/drain regions 731 using a photolithography process and an etching process similar to those used to pattern the first semiconductor sheets, the second semiconductor sheets, the p-type well 901 and the n-type well 902 in sub-step 511 of the method 500, so as to form a plurality of recesses, each of which is disposed between two adjacent ones of the gate electrodes 747 and exposes the source/drain regions disposed between said two adjacent ones of the gate electrodes 747; (b) depositing a conductive material for forming the contact lines 751 on the semiconductor structure to fill the recesses using, for example, PVD, CVD, ALD, other suitable techniques, or combinations thereof; and (c) removing an excess of the conductive material using, for example, CMP, or other suitable planarization techniques, so as to expose the gate electrodes 747. Portions of the conductive material that remain in the recesses respectively serve as the contact lines 751. In some embodiments, the conductive material may include, for example, copper, cobalt, ruthenium, molybdenum, chromium, tungsten, manganese, rhodium, iridium, nickel, palladium, platinum, silver, gold, aluminum, or alloys thereof.

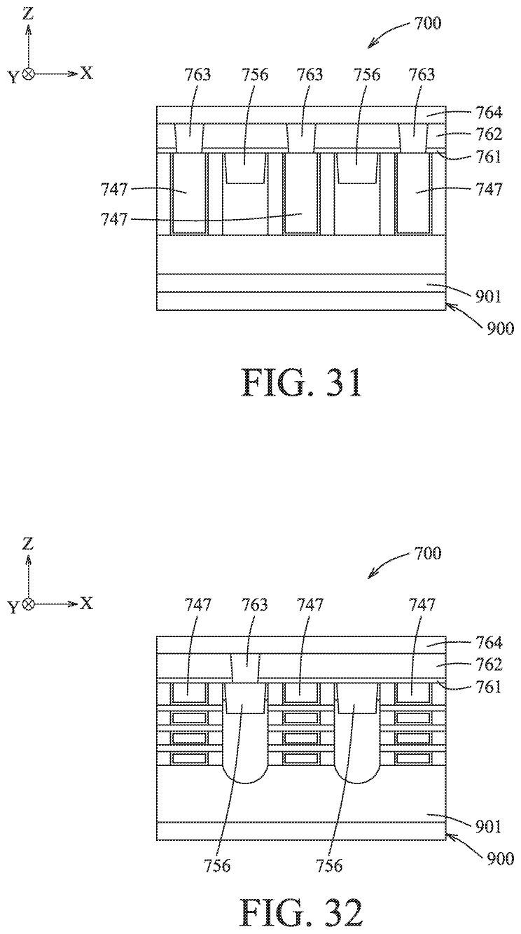

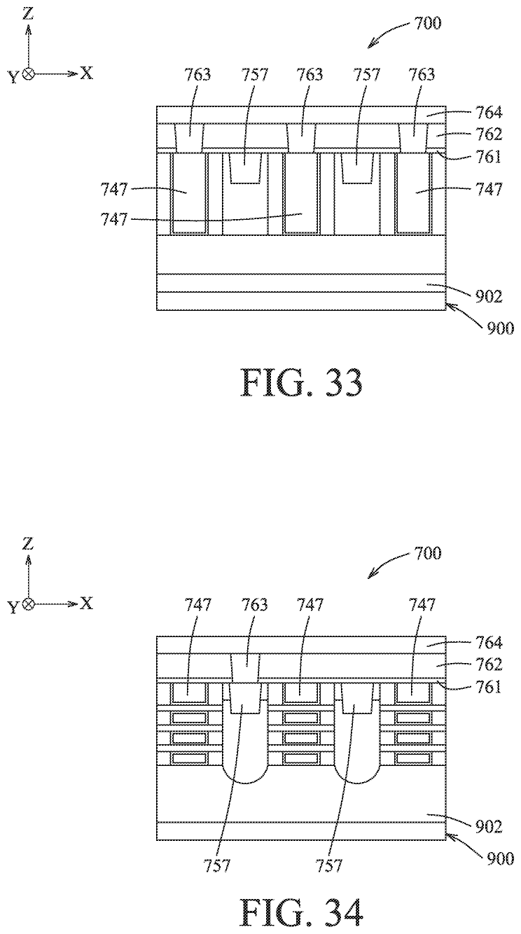

Referring to FIGS. 13 and 31-34, where FIG. 31 is a view similar to FIG. 27, FIG. 32 is a view similar to FIG. 28, FIG. 33 is a view similar to FIG. 29, and FIG. 34 is a view similar to FIG. 30, the method 500 then proceeds to step 53, where an etch stop layer 761, a dielectric layer 762, a plurality of vias 763 and a plurality of conductive lines 764 are formed. The etch stop layer 761 is disposed on the semiconductor structure 700 depicted in FIGS. 27-30. The dielectric layer 762 is disposed on the etch stop layer 761. The vias 763 are formed in the etch stop layer 761 and the dielectric layer 762. Each of the vias 763 is in contact with a corresponding one of the gate electrodes 747 and the first and second contact segments 756, 757 of the contact lines 751 (see FIG. 26). The conductive lines 764 are disposed on the dielectric layer 762 and the vias 763. Each of the conductive lines 764 extends in the X direction, and is in contact with at least one of the vias 763. In some embodiments, the etch stop layer 761 may be formed by a suitable deposition process, such as PVD, CVD, ALD, other suitable techniques, or combinations thereof. In some embodiments, the etch stop layer 761 may include, for example, aluminum compounds (e.g., aluminum nitride, aluminum oxynitride, aluminum oxide, etc.), silicon compounds (e.g., silicon oxycarbide, silicon carbonitride, silicon nitride, silicon oxycarbonitride, etc.), other suitable materials, or combinations thereof. In some embodiments, the dielectric layer 762 may be formed by a suitable deposition process, such as PVD, CVD, ALD, PECVD, plasma-enhanced atomic layer deposition (PEALD), other suitable techniques, or combinations thereof. In some embodiments, the dielectric layer 762 may include, for example, a low-k dielectric material, such as silicon oxide, silicon nitride, silicon carbide, silicon oxycarbide, silicon oxynitride, silicon carbonitride, silicon oxycarbonitride, other suitable materials, or combinations thereof. In some embodiments, the vias 763 may be formed by: (a) patterning the dielectric layer 762 and the etch stop layer 761 using a photolithography process and an etching process similar to those used to pattern the first semiconductor sheets, the second semiconductor sheets, the p-type well 901 and the n-type well 902 in sub-step 511 of the method 500, so as to form a plurality of recesses, each of which is disposed on and exposes a corresponding one of the gate electrodes 747, the first contact segments 756 and the second contact segments 757; (b) depositing a first conductive material for forming the vias 763 on the semiconductor structure to fill the recesses using, for example, PVD, CVD, ALD, other suitable techniques, or combinations thereof; and (c) removing an excess of the first conductive material using, for example, CMP, or other suitable planarization techniques, so as to expose the dielectric layer 762. Portions of the first conductive material that remains in the recesses respectively serve as the vias 763. In some embodiments, the first conductive material may include, for example, copper, cobalt, ruthenium, molybdenum, chromium, tungsten, manganese, rhodium, iridium, nickel, palladium, platinum, silver, gold, aluminum, or alloys thereof. In some embodiments, the conductive lines 764 may be formed by: (a) depositing a second conductive material for forming the conductive lines 764 on the dielectric layer 762 and the vias 763 using, for example, PVD, CVD, ALD, other suitable techniques; and (b) patterning the second conductive material using a photolithography process and an etching process similar to those used to pattern the first semiconductor sheets, the second semiconductor sheets, the p-type well 901 and the n-type well 902 in sub-step 511 of the method 500, so as to form the conductive lines 764. In some embodiments, the second conductive material may include, for example, copper, cobalt, ruthenium, molybdenum, chromium, tungsten, manganese, rhodium, iridium, nickel, palladium, platinum, silver, gold, aluminum, or alloys thereof.

In accordance with some embodiments of the present disclosure, a semiconductor device includes an n-type transistor, a first contact segment, a p-type transistor and a second contact segment. The n-type transistor includes a first source/drain region and a second source/drain region that are spaced apart from each other in a first direction transverse to a second direction. The second direction extends from bottom to top of the semiconductor device. The first contact segment extends along a third direction transverse to the first direction and the second direction, partially overlaps the first source/drain region of the n-type transistor, and is in contact with the first source/drain region of the n-type transistor. The p-type transistor includes a first source/drain region and a second source/drain region that are spaced apart from each other in the first direction. The second contact segment extends along the third direction, partially overlaps the first source/drain region of the p-type transistor, and is in contact with the first source/drain region of the p-type transistor. The width in the third direction of a portion of the first contact segment that overlaps the first source/drain region of the n-type transistor is different from a width in the third direction of a portion of the second contact segment that overlaps the first source/drain region of the p-type transistor.

In accordance with some embodiments of the present disclosure, a difference between the width in the third direction of the portion of the first contact segment that overlaps the first source/drain region of the n-type transistor and the width in the third direction of the portion of the second contact segment that overlaps the first source/drain region of the p-type transistor falls within a range of from 0.5 nm to 10 nm.

In accordance with some embodiments of the present disclosure, the width in the third direction of the portion of the first contact segment that overlaps the first source/drain region of the n-type transistor is different from a width in the third direction of a portion of the first contact segment that is non-overlapping with the first source/drain region of the n-type transistor.

In accordance with some embodiments of the present disclosure, a difference between the width in the third direction of the portion of the first contact segment that overlaps the first source/drain region of the n-type transistor and the width in the third direction of the portion of the first contact segment that is non-overlapping with the first source/drain region of the n-type transistor falls within a range of from 0.5 nm to 10 nm.

In accordance with some embodiments of the present disclosure, the width in the third direction of the portion of the second contact segment that overlaps the first source/drain region of the p-type transistor is different from a width in the third direction of a portion of the second contact segment that is non-overlapping with the first source/drain region of the p-type transistor.

In accordance with some embodiments of the present disclosure, a difference between the width in the third direction of the portion of the second contact segment that overlaps the first source/drain region of the p-type transistor and the width in the third direction of the portion of the second contact segment that is non-overlapping with the first source/drain region of the p-type transistor falls within a range of from 0.5 nm to 10 nm.

In accordance with some embodiments of the present disclosure, a height of the first contact segment in the second direction is different from a height of the second contact segment in the second direction.

In accordance with some embodiments of the present disclosure, a semiconductor device includes a first circuit and a second circuit. The second circuit has a connected poly pitch that is larger than a connected poly pitch of the first circuit. Each of the first circuit and the second circuit includes an n-type transistor, a first contact segment, a p-type transistor and a second contact segment, where the n-type transistor includes a first source/drain region and a second source/drain region, the first contact segment partially overlaps the first source/drain region of the n-type transistor and is in contact with the first source/drain region of the n-type transistor, the p-type transistor includes a first source/drain region and a second source/drain region, and the second contact segment partially overlaps the first source/drain region of the p-type transistor and is in contact with the first source/drain region of the p-type transistor. With respect to the first circuit, a width of a portion of the first contact segment that overlaps the first source/drain region of the n-type transistor is equal to a width of a portion of the second contact segment that overlaps the first source/drain region of the p-type transistor. With respect to the second circuit, a width of a portion of the first contact segment that overlaps the first source/drain region of the n-type transistor is different from a width of a portion of the second contact segment that overlaps the first source/drain region of the p-type transistor.

In accordance with some embodiments of the present disclosure, with respect to the second circuit, a difference between the width of the portion of the first contact segment that overlaps the first source/drain region of the n-type transistor and the width of the portion of the second contact segment that overlaps the first source/drain region of the p-type transistor falls within a range of from 0.5 nm to 10 nm.

In accordance with some embodiments of the present disclosure, with respect to the second circuit, the width of the portion of the first contact segment that overlaps the first source/drain region of the n-type transistor is different from a width of a portion of the first contact segment that is non-overlapping with the first source/drain region of the n-type transistor.

In accordance with some embodiments of the present disclosure, with respect to the second circuit, the width of the portion of the second contact segment that overlaps the first source/drain region of the p-type transistor is different from a width of a portion of the second contact segment that is non-overlapping with the first source/drain region of the p-type transistor.

In accordance with some embodiments of the present disclosure, with respect to the second circuit, a height of the first contact segment is different from a height of the second contact segment.

In accordance with some embodiments of the present disclosure, the width of the portion of the first contact segment of the second circuit that overlaps the first source/drain region of the n-type transistor of the second circuit is larger than the width of the portion of the first contact segment of the first circuit that overlaps the first source/drain region of the n-type transistor of the first circuit.

In accordance with some embodiments of the present disclosure, a ratio of the width of the portion of the first contact segment of the second circuit that overlaps the first source/drain region of the n-type transistor of the second circuit to the width of the portion of the first contact segment of the first circuit that overlaps the first source/drain region of the n-type transistor of the first circuit is no less than 1.1.

In accordance with some embodiments of the present disclosure, the width of the portion of the second contact segment of the second circuit that overlaps the first source/drain region of the p-type transistor of the second circuit is larger than the width of the portion of the second contact segment of the first circuit that overlaps the first source/drain region of the p-type transistor of the first circuit.

In accordance with some embodiments of the present disclosure, a ratio of the width of the portion of the second contact segment of the second circuit that overlaps the first source/drain region of the p-type transistor of the second circuit to the width of the portion of the second contact segment of the first circuit that overlaps the first source/drain region of the p-type transistor of the first circuit is no less than 1.1.

In accordance with some embodiments of the present disclosure, a method for manufacturing a semiconductor device includes: forming an n-type transistor and a p-type transistor, each of which includes a first source/drain region and a second source/drain region; and forming a first contact segment and a second contact segment, the first contact segment partially overlapping the first source/drain region of the n-type transistor, and being in contact with the first source/drain region of the n-type transistor, the second contact segment partially overlapping the first source/drain region of the p-type transistor, and being in contact with the first source/drain region of the p-type transistor. A width of a portion of the first contact segment that overlaps the first source/drain region of the n-type transistor is different from a width of a portion of the second contact segment that overlaps the first source/drain region of the p-type transistor.

In accordance with some embodiments of the present disclosure, the width of the portion of the first contact segment that overlaps the first source/drain region of the n-type transistor is different from a width of a portion of the first contact segment that is non-overlapping with the first source/drain region of the n-type transistor.

In accordance with some embodiments of the present disclosure, the width of the portion of the second contact segment that overlaps the first source/drain region of the p-type transistor is different from a width of a portion of the second contact segment that is non-overlapping with the first source/drain region of the p-type transistor.

In accordance with some embodiments of the present disclosure, a height of the first contact segment is different from a height of the second contact segment.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
an n-type transistor including a first source/drain region and a second source/drain region that are spaced apart from each other in a first direction transverse to a second direction, the second direction extending from bottom to top of the semiconductor device;
a first contact segment extending along a third direction transverse to the first direction and the second direction, partially overlapping the first source/drain region of the n-type transistor, and being in contact with the first source/drain region of the n-type transistor;
a p-type transistor including a first source/drain region and a second source/drain region that are spaced apart from each other in the first direction; and
a second contact segment extending along the third direction, partially overlapping the first source/drain region of the p-type transistor, and being in contact with the first source/drain region of the p-type transistor;
wherein a width in the third direction of a portion of the first contact segment that overlaps the first source/drain region of the n-type transistor is different from a width in the third direction of a portion of the second contact segment that overlaps the first source/drain region of the p-type transistor.

2. The semiconductor device according to claim 1, wherein a difference between the width in the third direction of the portion of the first contact segment that overlaps the first source/drain region of the n-type transistor and the width in the third direction of the portion of the second contact segment that overlaps the first source/drain region of the p-type transistor falls within a range of from 0.5 nm to 10 nm.

3. The semiconductor device according to claim 1, wherein the width in the third direction of the portion of the first contact segment that overlaps the first source/drain region of the n-type transistor is different from a width in the third direction of a portion of the first contact segment that is non-overlapping with the first source/drain region of the n-type transistor.

4. The semiconductor device according to claim 3, wherein a difference between the width in the third direction of the portion of the first contact segment that overlaps the first source/drain region of the n-type transistor and the width in the third direction of the portion of the first contact segment that is non-overlapping with the first source/drain region of the n-type transistor falls within a range of from 0.5 nm to 10 nm.

5. The semiconductor device according to claim 1, wherein the width in the third direction of the portion of the second contact segment that overlaps the first source/drain region of the p-type transistor is different from a width in the third direction of a portion of the second contact segment that is non-overlapping with the first source/drain region of the p-type transistor.

6. The semiconductor device according to claim 5, wherein a difference between the width in the third direction of the portion of the second contact segment that overlaps the first source/drain region of the p-type transistor and the width in the third direction of the portion of the second contact segment that is non-overlapping with the first source/drain region of the p-type transistor falls within a range of from 0.5 nm to 10 nm.

7. The semiconductor device according to claim 1, wherein a height of the first contact segment in the second direction is different from a height of the second contact segment in the second direction.

8. A semiconductor device comprising:
a first circuit; and
a second circuit having a connected poly pitch that is larger than a connected poly pitch of the first circuit;
wherein each of the first circuit and the second circuit includes
an n-type transistor including a first source/drain region and a second source/drain region,
a first contact segment partially overlapping the first source/drain region of the n-type transistor, and being in contact with the first source/drain region of the n-type transistor,
a p-type transistor including a first source/drain region and a second source/drain region, and
a second contact segment partially overlapping the first source/drain region of the p-type transistor, and being in contact with the first source/drain region of the p-type transistor;
wherein, with respect to the first circuit, a width of a portion of the first contact segment that overlaps the first source/drain region of the n-type transistor is equal to a width of a portion of the second contact segment that overlaps the first source/drain region of the p-type transistor;
wherein, with respect to the second circuit, a width of a portion of the first contact segment that overlaps the first source/drain region of the n-type transistor is different from a width of a portion of the second contact segment that overlaps the first source/drain region of the p-type transistor.

9. The semiconductor device according to claim 8, wherein, with respect to the second circuit, a difference between the width of the portion of the first contact segment that overlaps the first source/drain region of the n-type transistor and the width of the portion of the second contact segment that overlaps the first source/drain region of the p-type transistor falls within a range of from 0.5 nm to 10 nm.

10. The semiconductor device according to claim 8, wherein, with respect to the second circuit, the width of the portion of the first contact segment that overlaps the first source/drain region of the n-type transistor is different from a width of a portion of the first contact segment that is non-overlapping with the first source/drain region of the n-type transistor.

11. The semiconductor device according to claim 8, wherein, with respect to the second circuit, the width of the portion of the second contact segment that overlaps the first source/drain region of the p-type transistor is different from a width of a portion of the second contact segment that is non-overlapping with the first source/drain region of the p-type transistor.

12. The semiconductor device according to claim 8, wherein, with respect to the second circuit, a height of the first contact segment is different from a height of the second contact segment.

13. The semiconductor device according to claim 8, wherein the width of the portion of the first contact segment of the second circuit that overlaps the first source/drain region of the n-type transistor of the second circuit is larger than the width of the portion of the first contact segment of the first circuit that overlaps the first source/drain region of the n-type transistor of the first circuit.

14. The semiconductor device according to claim 13, wherein a ratio of the width of the portion of the first contact segment of the second circuit that overlaps the first source/drain region of the n-type transistor of the second circuit to the width of the portion of the first contact segment of the first circuit that overlaps the first source/drain region of the n-type transistor of the first circuit is no less than 1.1.

15. The semiconductor device according to claim 8, wherein the width of the portion of the second contact segment of the second circuit that overlaps the first source/drain region of the p-type transistor of the second circuit is larger than the width of the portion of the second contact segment of the first circuit that overlaps the first source/drain region of the p-type transistor of the first circuit.

16. The semiconductor device according to claim 15, wherein a ratio of the width of the portion of the second contact segment of the second circuit that overlaps the first source/drain region of the p-type transistor of the second circuit to the width of the portion of the second contact segment of the first circuit that overlaps the first source/drain region of the p-type transistor of the first circuit is no less than 1.1.

17. A method for manufacturing a semiconductor device, comprising:
forming an n-type transistor and a p-type transistor, each of which includes a first source/drain region and a second source/drain region; and
forming a first contact segment and a second contact segment, the first contact segment partially overlapping the first source/drain region of the n-type transistor, and being in contact with the first source/drain region of the n-type transistor, the second contact segment partially overlapping the first source/drain region of the p-type transistor, and being in contact with the first source/drain region of the p-type transistor;
wherein a width of a portion of the first contact segment that overlaps the first source/drain region of the n-type transistor is different from a width of a portion of the second contact segment that overlaps the first source/drain region of the p-type transistor.

18. The method according to claim 17, wherein the width of the portion of the first contact segment that overlaps the first source/drain region of the n-type transistor is different from a width of a portion of the first contact segment that is non-overlapping with the first source/drain region of the n-type transistor.

19. The method according to claim 17, wherein the width of the portion of the second contact segment that overlaps the first source/drain region of the p-type transistor is different from a width of a portion of the second contact segment that is non-overlapping with the first source/drain region of the p-type transistor.

20. The method according to claim 17, wherein a height of the first contact segment is different from a height of the second contact segment.
